(19) United States
(12) Patent Application Publication
(10) Pub. No.: US 2026/0141967 A1
(43) Pub. Date: May 21, 2026

(54) METHODS AND CIRCUITS FOR TESTING THROUGH SILICON VIAS

(71) Applicant: Micron Technology, Inc., Boise, ID (US)

(72) Inventor: Jaeil Kim, Suwanee, GA (US)

(21) Appl. No.: 19/373,810

(22) Filed: Oct. 30, 2025

Related U.S. Application Data
(60) Provisional application No. 63/722,497, filed on Nov. 19, 2024.

(51) Int. Cl. G11C 29/10; H01L 23/00; H01L 25/065; H01L 25/18; H10B 80/00

(52) U.S. Cl. CPC G11C 29/10; H10B 80/00; H10W 90/00; H10W 90/284; H10W 90/297; H10W 90/792

(57) ABSTRACT

Methods, systems, and devices for methods and circuits for testing through silicon vias are described. A memory system including multiple stacked memory dies may include circuitry for testing one or more vias that couple the stacked memory dies. First circuitry may be coupled with the vias of the memory system, second circuitry may be coupled with the first circuitry and a controller, and third circuitry may receive output signaling from one or more memory dies of the memory system. The second circuitry may use the first circuitry to route test signaling through one or more vias (or a portion of one or more vias) based on signaling received at the second circuitry. The third circuitry may receive output signaling from the memory system based on the test signaling and may determine, output, and/or store failure information associated with the vias based on the output signaling.

### CROSS REFERENCE

The present Application for Patent claims priority to U.S. Patent Application No. 63/722,497 by Kim, entitled “METHODS AND CIRCUITS FOR TESTING THROUGH SILICON VIAS,” filed Nov. 19, 2024, which is assigned to the assignee hereof, and which is expressly incorporated by reference in its entirety herein.

### TECHNICAL FIELD

The following relates to one or more semiconductor systems (e.g., or memory systems), including methods and circuits for testing through silicon vias.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports methods and circuits for testing through silicon vias (TSVs) in accordance with examples as disclosed herein.

FIG. 2 shows an example of a system that supports methods and circuits for testing TSVs in accordance with examples as disclosed herein.

FIG. 3 shows an example of circuitry that supports methods and circuits for testing TSVs in accordance with examples as disclosed herein.

FIG. 4 show examples of circuitry that supports methods and circuits for testing TSVs in accordance with examples as disclosed herein.

FIGS. 5A and 5B show examples of circuitry portions that support methods and circuits for testing TSVs in accordance with examples as disclosed herein.

FIG. 6 shows an example of a timing diagram that supports methods and circuits for testing TSVs in accordance with examples as disclosed herein.

FIG. 7 shows an example of a flowchart that supports methods and circuits for testing TSVs in accordance with examples as disclosed herein.

FIG. 8 shows a block diagram of a memory system that supports methods and circuits for testing TSVs in accordance with examples as disclosed herein.

FIG. 9 shows a flowchart illustrating a method or methods that support methods and circuits for testing TSVs in accordance with examples as disclosed herein.

### DETAILED DESCRIPTION

Some semiconductor systems (e.g., memory systems, processor systems, systems having a combination of memory and processing) may include a stack of components (e.g., semiconductor dies). The stack may include one or more memory dies (e.g., memory dies, array dies, memory array dies, slices) or one or more stacks of memory dies that are stacked with a logic die that is operable to access a set of memory arrays distributed across the one or more memory dies. Such a stacked architecture may be implemented as part of a high bandwidth memory (HBM) system or a tightly-coupled dynamic random access memory (TCDRAM) system, among other examples, and may support solutions for memory-centric logic, such as graphics processing units (GPUs), among other implementations.

In some examples, an HBM system may include one or more memory dies coupled with (e.g., bonded to, stacked on) a logic die. In some examples, a TCDRAM system may be closely coupled with (e.g., physically coupled with, electrically coupled with, directly coupled with) a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some semiconductor systems (e.g., stacked memory systems, HBM systems, TCDRAM systems, three dimensional (3D) memory systems) may include a plurality of vias (e.g., through silicon vias (TSVs)) to communicate signaling with and between each memory die (e.g., layer, level) of the semiconductor system. For example, the vias may include conductive material (e.g., formed during manufacturing of the semiconductor system) to couple each memory die with a previous (e.g., lower) memory die of the semiconductor system. In some examples, each via may be formed to provide relatively low-resistance access between a logic die (or other dies) and one or more memory cells on one or more (e.g., all) of the memory dies in the semiconductor system (e.g., such as to allow a controller to read or write to the memory cells). However, some vias may be defective or otherwise fail, which may result in a relatively high resistance between components, or may not couple memory dies of the semiconductor system as intended, which may reduce an efficiency and utility of the semiconductor system. In some examples, testing individual vias after the semiconductor system is manufactured may involve intensive efforts from a user or manufacturer, or may otherwise not be possible. Thus, techniques for testing vias of a semiconductor system after the semiconductor system is manufactured may be beneficial.

Techniques described herein may include a memory system (e.g., a semiconductor system, a stacked memory system, one or more stacked memory dies) that includes circuitry for testing vias of the stacked memory system and methods for performing such tests. One or more of the memory dies of a stacked memory system may include first circuitry (e.g., routing circuitry) coupled with the vias of the memory system and second circuitry (e.g., selection circuitry, control circuitry) coupled with a controller and the first circuitry. The memory system may also include third circuitry (e.g., test results generation circuitry, test results storing circuitry) configured to receive output signals from the one or more memory dies of the memory system based on test signaling.

In some examples, the second circuitry may receive signaling from the controller, and may use one or more portions of the first circuitry to route test signaling from a first memory die to a second memory die through a via (or a portion of a via) of the memory system. The third circuitry may be coupled with the second memory die and may receive output signaling from the second memory die that is based on the test signaling. Additionally, or alternatively, the third circuitry may determine, output, and/or store failure information associated with the vias of the memory system based on the output signaling. In some examples, the signaling received at the second circuitry may test a via between a middle memory die of the memory system (e.g., a die other than a top memory die) and a memory die below (e.g., under) the middle memory die, which may allow for testing of a portion of a via. Additionally, or alternatively, the second circuitry may include one or more shift registers that may cause the first circuitry to sequentially route the test signaling through each via of the plurality of vias (e.g., sequentially testing each via or a portion of each via), and the failure information may be based on such sequential routing. Thus, one or more failing vias may be determined based on the failure information, and a user or manufacturer of the memory system may modify, utilize, or discard the memory system accordingly. Such testing may advantageously occur after the semiconductor system is manufactured. In some cases, manufacturing processes may be adjusted based on the failure information to improve yields of future manufactured devices.

In addition to applicability in memory systems as described herein, techniques for testing TSVs may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling the testing of individual vias and output or storage of failure information associated with the vias, which may allow a manufacturer or user to detect failures and act accordingly.

Features of the disclosure are illustrated and described in the context of systems and architectures. Features of the disclosure are further illustrated and described in the context of circuitry, timing diagrams, and flowcharts.

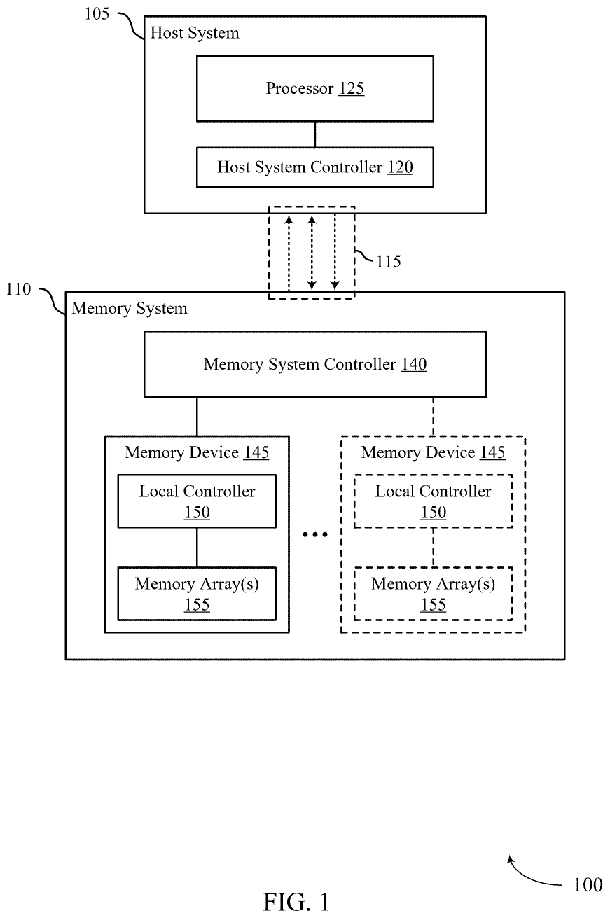

FIG. 1 shows an example of a system 100 that supports methods and circuits for testing TSVs in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a TCDRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

According to techniques described herein, the memory system 110 (e.g., a semiconductor system, a stacked memory system, one or more stacked memory dies) may include circuitry for testing vias of the stacked memory system (e.g., TSV between the memory device 145), and may use methods disclosed here for performing such tests. One or more of the memory dies (e.g., memory devices) of the memory system 110 (e.g., a stacked memory system) may include first circuitry (e.g., routing circuitry) coupled with the vias of the memory system 110 and second circuitry (e.g., selection circuitry, control circuitry) coupled with the first circuitry and a controller (e.g., the memory system controller 140, the host system 105, a local controller 150). The memory system 110 may also include third circuitry (e.g., test results generation circuitry, test results storing circuitry) configured to receive output signals from the one or more memory dies of the memory system that is based on test signaling.

In some examples, the second circuitry may receive signaling from the controller, and may use one or more portions of the first circuitry to route test signaling from a first memory die to a second memory die through a via (or a portion of a via) of the memory system 110. The third circuitry may be coupled with the second memory die and may receive output signaling from the second memory die that is based on the test signaling. Additionally, or alternatively, the third circuitry may determine, output, and/or store failure information associated with the vias of the memory system 110 based on the output signaling. In some examples, the signaling may indicate any two memory dies of the memory system 110 (e.g., including a top memory die, a bottom memory die, a die other than the top or bottom memory dies, or any combination thereof) to be the first memory die and second memory die, which may allow for testing a portion of a via. Additionally, or alternatively, the second circuitry may include one or more shift registers that may cause the first circuitry to sequentially route the test signaling through each via of the plurality of vias (e.g., sequentially testing each via or a portion of each via), and the failure information may be based on such sequential routing. Thus, one or more failing vias may be determined based on the failure information, and a user or manufacturer of the memory system 110 may modify, utilize, or discard the memory system 110 accordingly. Such testing may advantageously occur after the semiconductor system is manufactured

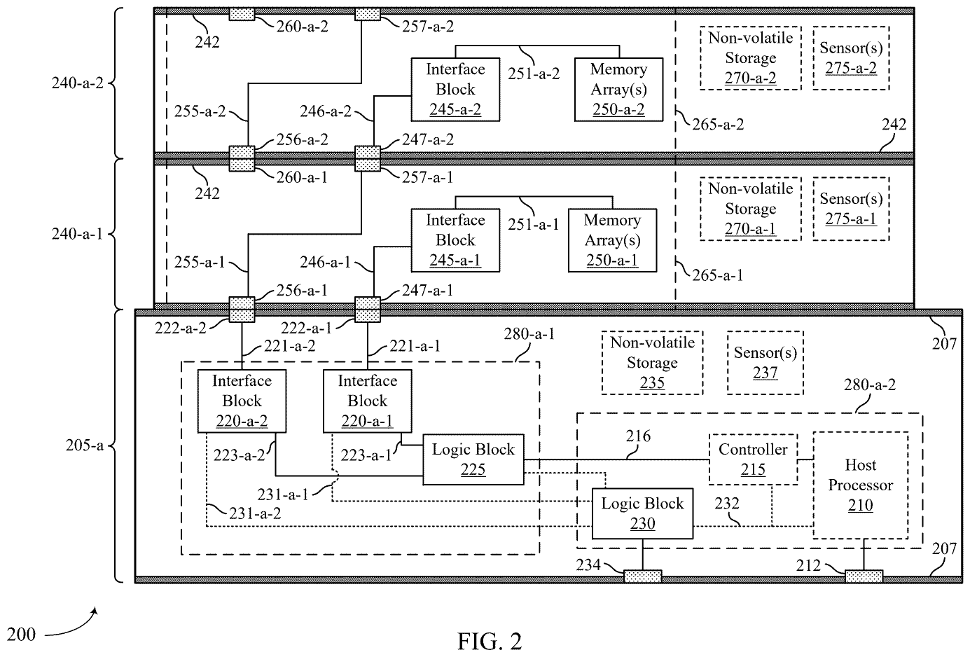

FIG. 2 shows an example of a system 200 (e.g., a semiconductor system, a system of coupled semiconductor dies, an HBM system, a TCDRAM system) that supports methods and circuits for testing TSVs in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., TCDRAM implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a TCDRAM implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a tightly-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

According to techniques described herein, the system 200 may include circuitry for testing vias of a stacked memory system and may use methods described herein for performing such tests. In some cases, the busses 255, the contacts (e.g., contacts 256, contacts 257, contacts 260), or any other conductive connection between two of the dies 205 and 240 (e.g., memory dies) may include or be included in a via (e.g., a TSV). The memory system 200 may include first circuitry (e.g., routing circuitry), second circuitry (e.g., selection circuitry, control circuitry), and third circuitry (e.g., test results generation circuitry, test results storing circuitry).

In some examples, the second circuitry may receive signaling from the controller to use one or more portions of the first circuitry to route test signaling from a first die 240 to a second die (e.g., a die 240, the die 205) through at least a via (or a portion of a via) of the system 200. The third circuitry may receive output signaling from the second memory die that is based on the test signaling, and may determine, output, and/or store failure information associated with the vias of the system 200 based on the output signaling. In some examples, the signaling may select any two memory dies as the first memory die and the second memory die, which may allow for testing of a portion of the via. Additionally, or alternatively, the second circuitry may include one or more shift registers that may cause the second circuitry to sequentially route the test signaling through each via of the vias (e.g., sequentially testing each via or a portion of each via), and the failure information may be based on such sequential routing. Thus, a manufacturer or user of the system 200 may determine one or more failing vias based on the failure information and may modify, utilize, or discard the system 200 accordingly. Such testing may advantageously occur after the semiconductor system is manufactured

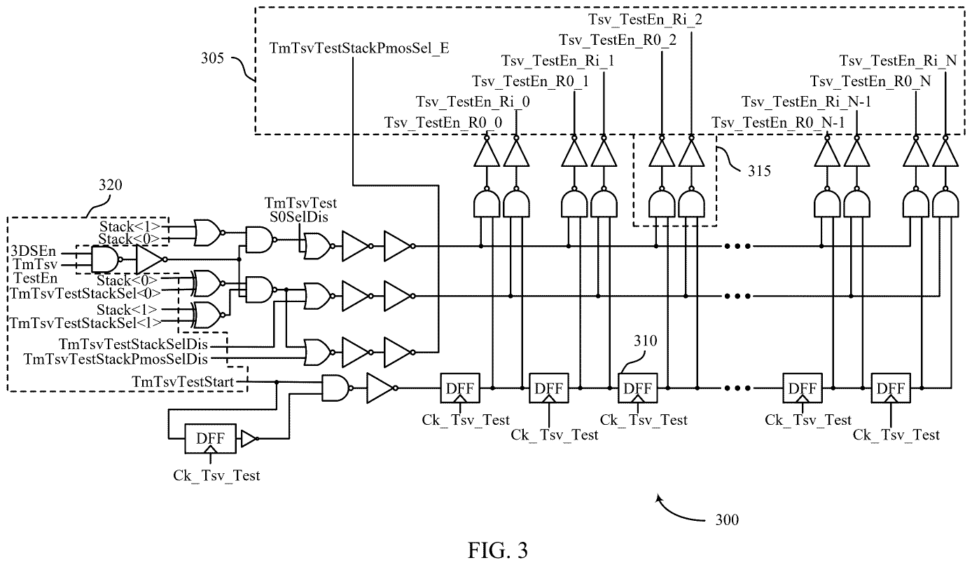

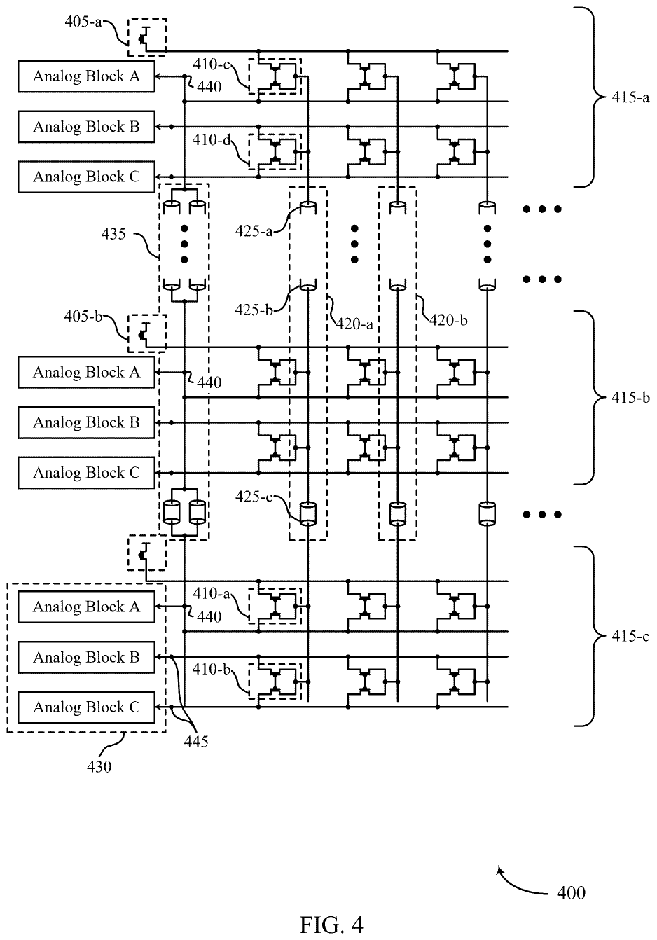

FIG. 3 shows an example of circuitry 300 (e.g., second circuitry, control circuitry, selection circuitry) that supports methods and circuits for testing TSVs in accordance with examples as disclosed herein. In some cases, aspects of the circuitry 300 may implement or be implemented by aspects of FIGS. 1 and 2. For example, the circuitry 300 may be an example of the second circuitry (e.g., control circuitry, selection circuitry) described herein with respect to FIGS. 1 and 2. In some aspects, the circuitry 300 may receive signaling 320 (e.g., one or more control signals, control signaling) from a controller (e.g., host system controller 120, memory system controller 140, local controller 150, controller 215, or any combination thereof, as described herein with respect to FIGS. 1 and 2) and may use the first circuitry (e.g., as described herein with respect to FIG. 4) to route test signaling through one or more vias. For example, the circuitry 300 may include logical components (e.g., logic gates, AND, NOT, OR, exclusive OR (XOR), NOT AND (NAND), NOT OR (NOR), exclusive NOR (XNOR)) and shift registers 310 (e.g., digital flip flop (DFF) components), and the circuitry 300 may output activation signals 305 based on the signaling 320 received from the controller, the logical components, and the shift registers 310.

In some aspects, each memory die (e.g., each slice) of the memory system may include (e.g., be coupled with) circuitry 300 (e.g., an instance of the circuitry 300). For example, the circuitry 300 of each memory die may be coupled with the first circuitry (e.g., circuitry 400, as described with respect to FIG. 4), and the circuitry 300 may be configured to receive signaling 320 from the controller and use the first circuitry to route test signaling (e.g., a test voltage, a test signal, a high voltage, VDD) between a first memory die and a second memory die of the memory system through one or more vias of the memory system. For example, the activation signals 305 output by the circuitry 300 may activate or deactivate one or more components of the first circuitry (e.g., as described with respect to FIG. 4).

In some cases, the signaling 320 received by the circuitry 300 of a respective memory die may indicate one or more parameters for testing the vias in the memory system. In some cases, one or more portions (e.g., common portions, common signals) of the signaling 320 may be received at the circuitry 300 of each memory die, and one or more portions of the signaling 320 may be die-specific (e.g., die-specific signals). For example, the signaling 320 received at the circuitry 300 of a respective memory die may include an indication of the respective memory die of the stack of memory dies, which may be two bits indicated by Stack <0> and Stack <1> (e.g., referred to collectively as Stack <1:0>). For example, each memory die may be associated with an index (e.g., a two bit index if the memory system includes up to four memory dies). The bits of Stack <1:0> may indicate the index of the respective memory die with which the instance of the second circuitry is coupled. The logical components of the circuitry 300 may produce different activation signals 305 based on Stack <1:0> to control the first circuitry, such as activating or deactivating pairs of selection transistors (e.g., as described with respect to FIG. 4).

The signaling may include an indication of a memory die at which the test signaling enters the one or more vias to be tested (e.g., a first memory die), which may be referred to as an upper memory die (e.g., slice) for via testing. For example, the memory system may test an entirety of a via (e.g., the entire via from the top memory die of the memory system to a bottom die of the memory system) or a portion of a via (e.g., from a first memory die to a second memory die, where at least one of the first memory die and the second memory die are a memory die other than the top memory die and the bottom memory die of the stack). In some cases, TmTsvTestStackSel <0> and TmTsvTestStackSel <1> (e.g., referred to collectively as TmTsvTestStackSel <1:0>) may be portions of the signaling 320 and may indicate an index of the upper memory die for via testing. That is, TmTsvTestStackSel <1:0> may allow for selection (e.g., control) of the upper memory die for via (e.g., TSV) testing. Based on the logical components of the circuitry 300, different values of TmTsvTestStackSel <1:0> may produce different activation signals 305 to activate different pairs of selection transistors (e.g., as described with respect to FIG. 4).

The signaling 320 may also include a shift register start signal (e.g., TmTsvTestStart, shift register pulse generation signal). For example, the shift registers 310 may cause the circuitry 300 to route (e.g., based on TmTsvTestStart, based on the shift register start signal) the test signaling from the upper memory die for via testing to a second memory die of the memory system (e.g., the bottom memory die) through each via of the plurality of vias (e.g., sequentially, in order). For example, each shift register 310 may be coupled with a set of logical components 315 of the circuitry 300, where each set of logical components 315 may output two (e.g., or any quantity) of the activation signals 305. Each set of logical components 315 may correspond to a via of the multiple vias of the memory system (e.g., as described with respect to FIG. 4) and may output activation signals 305 that activate (e.g., or deactivate) a pair of selection components coupled with a via at the memory die that include the circuitry 300.

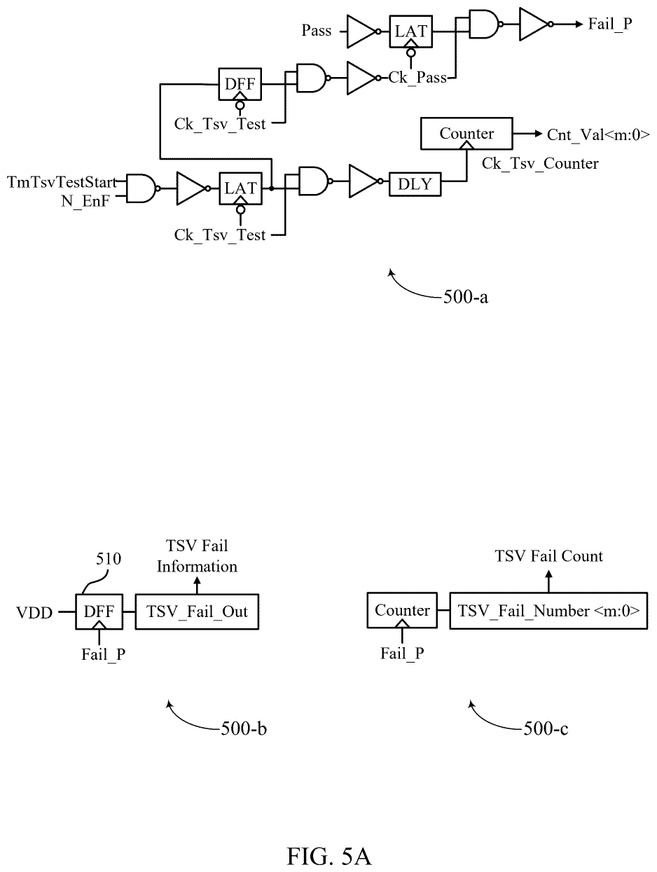

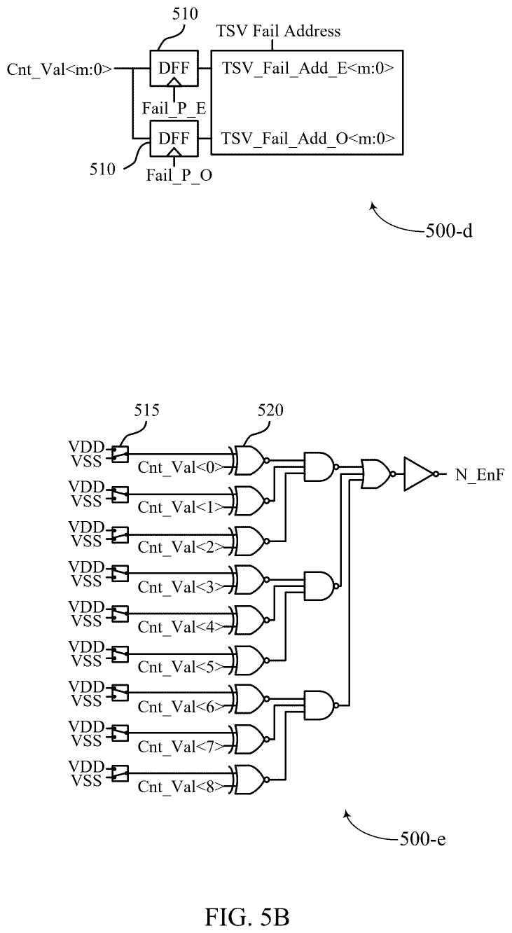

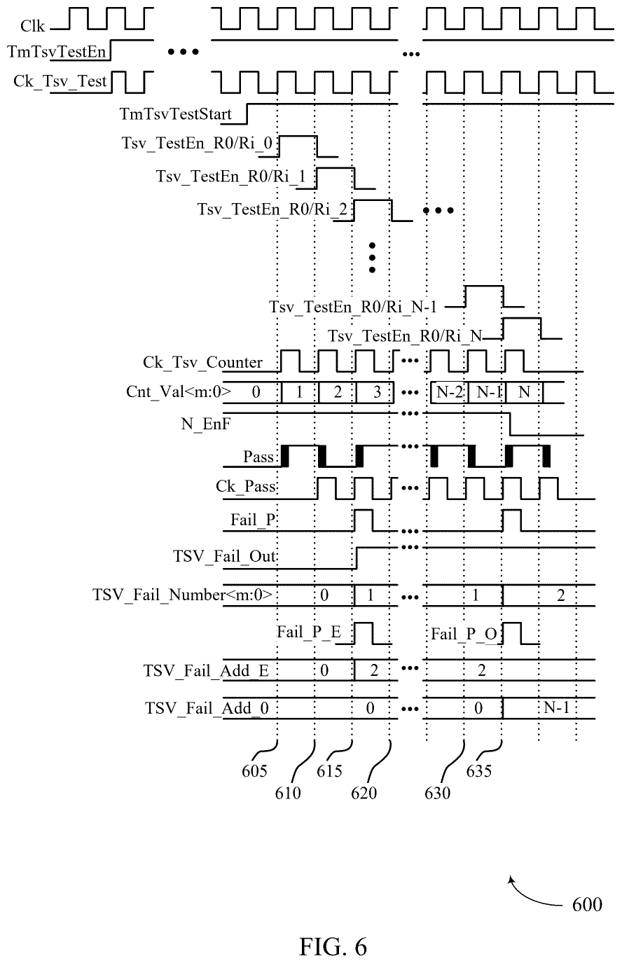

A portion of the signaling 320 may initiate a pulse generation by the shift register 310 to sequentially test the vias in the memory system. For example, based on the activation of TmTsvTestStart, a relatively high pulse may sequentially pass through and activate each shift register 310 according to a clock signal (e.g., Ck_Tsv_Test, as described with respect to FIG. 6), which is received at each shift register 310. When a shift register 310 is activated, the set of logical components 315 coupled with the shift register 310 may be activated, allowing for the testing of a via corresponding to the set of logical components 315 (e.g., as further described with respect to FIG. 4). Thus, the circuitry 300 may provide for the sequential testing of each via (e.g., or a portion of each via, based on TmTsvTestStackSel <1:0>) in the memory system, where failure information associated with the vias of the memory system (e.g., as described with respect to FIG. 5) may be based on the testing of each via.

The signaling 320 may also include shift register inversion signaling (e.g., TmTsvTestEnS0Inv, TmTsvTestEnSiInv, not shown), which may invert an output phase of the shift registers 310 associated with the respective memory die receiving the signaling 320, the shift registers 310 associated with the upper memory die for via testing (e.g., the first memory die), or both. The signaling may also include a test enable signal (e.g., TmTsvTestEn). The test enable signaling may enable (e.g., activate, begin) the clock signal (e.g., Ck_Tsv_Test) used by the circuitry 300, and may be an example of a reset flag (RSTF) used by the shift registers 310 for testing the vias.

The signaling 320 may also include source connection transistor activation (e.g., or deactivation) signaling (e.g., TmTsvTestStackPmosSelDis), which may deactivate (e.g., disable, increase a resistance of a channel of) a source transistor (e.g., such as a source transistor 405 described with respect to FIG. 4) of the respective memory die receiving the signaling. The signaling may also include selection transistor disable signaling (e.g., TmTsvTestS0SelDis, TmTsvTestStackSelDis), which may, in conjunction with one or more other portions of the signaling 320 (e.g., Stack <1:0>, TmTsvTestStackSel <1:0>), generate the activation signals 305 using the logical components to activate or deactivate one or more pairs of selection transistors (e.g., such as the pairs of selection transistors 410 described with respect to FIG. 4) of the respective memory die receiving the signaling.

Each of the activation signals 305 may activate (e.g., or deactivate) a pair or selection transistors (e.g., a pair of selection transistors 410) of the first circuitry (e.g., circuitry 400) to route test signaling (e.g., a high voltage, VDD) through one or more vias (e.g., a portion of one or more vias) between the upper memory die for testing the vias and a second memory die (e.g., the bottom memory die) of the memory system. For example, each set of logical components 315 may output two activation signals 305, which may be referred to as Tsv_TestEn_Rx_y and Tsv_TestEn_Ri_y, where x may be an index corresponding to the respective memory die receiving the signaling, y may be an index corresponding to a via associated with the activation signal 305, and i may be an index associated with the upper memory die for via testing (e.g., based on TmTsvTestStackSel <1:0>). The circuitry 300 shown in FIG. 3 may be associated with a bottom memory die of a memory system, and thus x may be “0,” but x may also be “1,” “2,” or “3,” for example, in a memory system that includes four memory dies.

As described with respect to FIG. 4, each activation signal 305 associated with a respective memory die and of the name format Tsv_TestEn_Ri_y (e.g., Tsv_TestEn_Ri_0,Tsv_TestEn_Ri_1, etc.) may activate or deactivate (e.g., control) a first pair of selection transistors (e.g., the pairs of selection transistors 410-a, the pair of selection transistors 410-c) of the respective memory die, which may be configured to couple a via with the output of a source transistor 405 associated with the respective memory die. Additionally, each activation signal 305 associated with the respective memory die and of the name format Tsv_TestEn_Rx_y (e.g., Tsv_TestEn_R0_0, Tsv_TestEn_R0_1, etc.) may control a second pair of selection transistors (e.g., the pair of selection transistors 410-b, the pair of selection transistors 410-d) of the respective memory die, which may route the test signaling from a via to one or more analog blocks (e.g., as described with respect to FIG. 4-B) . Additionally, the activation signal 305 referred to as TmTsvTestStackPmosSel_E may activate (e.g., or deactivate) a source transistor 405 associated with the respective memory die. In some aspects, FIG. 4 may illustrate the first circuitry and how the activation signals 305 control one or more components of the first circuitry.

FIG. 4 shows an example of circuitry 400 (e.g., first circuitry, routing circuitry) that supports methods and circuits for testing TSVs in accordance with examples as disclosed herein. In some cases, aspects of the circuitry 400 may implement or be implemented by aspects of FIGS. 1-3. For example, the circuitry 400 may include one or more source transistors 405 and one or more pairs of selection transistors 410, each of which may be controlled (e.g., activated or deactivated) by one or more of the activation signals 305 described with respect to FIG. 3. Additionally, the circuitry 400 may include one or more portions 415, where each portion 415 is within (e.g., coupled with, part of) a memory die of the memory system (e.g., a slice of the memory system, such as the memory dies described with respect to FIGS. 1-3). The memory system may also include multiple vias 420, where each via 420 may include one or more via portions 425 (e.g., in the case of 4 memory dies, via portions 425-a, 425-b, and 425-c). For example, the circuitry 400 may be coupled with each via portion 425 of each via 420. In some aspects, the circuitry 400 may be used to route test signaling (e.g., a high voltage, VDD) through one or more vias 420 or via portions 425 to determine one or more vias 420 or via portions 425 that are failing (e.g., failing vias or failing via portions).

In some cases, the vias 420 may extend through the memory system (e.g., the stack of memory dies) and may be configured to route signaling between two or more of the memory dies (e.g., at least a first memory die of the stack of memory dies and a second memory die of the stack of memory dies). For example, the vias may have been formed during manufacturing, where a manufacturing process may create via portions 425 in a first memory die to couple the first memory die with a second memory die (e.g., a lower memory die, a memory die below the first memory die). In some cases, the vias 420 allow a memory controller to access each memory die, to one or more memory cells in each memory die, or both.

In some memory systems (e.g., double data rate (DDR) 5 3D systems (3DS)), each memory die may be the same (e.g., include the same components, have a same layout or format, be manufactured in the same process), whereas other memory systems may include a different bottom memory die that includes additional or different portions or components (e.g., controller logic, access components, such as HBM). Thus, the portions 415 of the circuitry 400 may be the same, and each portion 415 may be capable of supplying output signaling from a corresponding memory die to the analog blocks 430 (e.g., the same analog blocks for all of the memory dies, which may include an analog block A, an analog block B, and an analog block C). For example, the memory system (e.g., or the analog blocks 430) may include a comparator similar to comparators in other memory technologies (e.g., HBM systems) to differentiate a source memory die of the output signaling.

Each portion of the circuitry 400 may include one or more transistors. For example, each portion 415 may include a source transistor 405, which may be configured to couple one or more first pairs of selections transistors (e.g., the pair of selection transistors 410-a, the pair of selection transistors 410-c) with a source of the test signaling. For example, a source transistor 405 may include a first node (e.g., a source node) coupled with a source of the test signaling and a gate coupled with one or more activation signals (e.g., TmTsvTestStackPmosSel_E) from the circuitry 300 of FIG. 3. Each first pair of selection transistors 410 may selectively couple a second node (e.g., a drain node) of the source transistor 405 with a via portion 425 that is below the portion 415. For example, the pair of selection transistors 410-c may selectively couple the second node of the source transistor 405 a with the via portion 425-a (e.g., and thus a via 420-a).

Each first pair of selection transistors 410 may also selectively couple the second node of the source transistor 405 with a reference via 435, which may be a more robust or reliable via (e.g., including multiple via portions 425 between each adjacent memory dies). Additionally, the reference via 435 may be coupled with a first output node 440 of each portion 415 (e.g., the bottom memory die, the second memory die), where the analog blocks 430 (e.g., part of the third circuitry, at least the analog block A) may be configured to receive output signaling associated with via testing from the first output node of each portion based on the first pair of selection transistors 410.

In some cases, each portion 415 of the circuitry 400 within each memory die may also include a second pair of selection transistors 410 (e.g., the pair of selection transistors 410-b, the pair of selection transistors 410-d) that may selectively couple a via 420 (e.g., a via portion 425 above the memory die) with one or more second output nodes 445 of the memory die. For example, the pair of selection transistors 410-b may selectively couple the via portion 425-c (e.g., and thus the via 420-a) with one or more of the second output nodes 445. In some cases, the analog blocks 430 (e.g., the third circuitry, at least analog blocks B and C) may be configured to receive output signaling associated with via testing from the second output node of each portion 415 based on the second pairs of selection transistors 410.

The source transistors 405 and the pairs of selection transistors 410 associated with a memory die may be activated or deactivated (e.g., controlled) based on the activation signals 305 from the circuitry 300 (e.g., described with respect to FIG. 3) associated with the memory die. For example, the control signal TmTsvTestStackPmosSel_E from circuitry 300 may activate or deactivate a source transistor 405 of a memory die. Additionally, or alternatively, the activation signals 305 referred to as Tsv_TestEn_Rx_y (e.g., as described with respect to FIG. 3) may activate or deactivate the second pair of selection transistors 410 (e.g., the pair of selection transistors 410-b, for example), and the activation signals 305 referred to as Tsv_TestEn_Ri_y (e.g., as described with respect to FIG. 3) may activate or deactivate the first pair of selection transistors 410 (e.g., the pair of selection transistors 410-a, for example).

Thus, the circuitry 300 may use the circuitry 400 to route test signaling through one or more vias 420 of a memory system. In one example, the circuitry 300 may use the circuitry 400 to route test signaling through the via 420-a (from the memory die coupled with the portion 415-a) to the memory die coupled with the portion 415-c. For example, the activation signaling 305 from the circuitry 300 coupled with the portion 415-a may activate the source transistor 405-a (e.g., while the activation signaling 305 from other instances of the circuitry 300 may not activate the other source transistors 405), which may couple the first pairs of selection transistors 410 of the portion 415-a with the test signaling. The activation signaling 305 from the circuitry 300 coupled with the portion 415-a may also activate the first pair of selection transistors 410-c (e.g., and deactivate the second pair of selection transistors 410- d) to couple the reference via 435 and the via portion 425-a (e.g., and thus the via 420-a) with the test signaling.

The activation signaling 305 from the circuitry 300 coupled with the portion 415-b may deactivate the source transistor 405-b and the pairs of selection transistors 410 in the portion 415-b. The activation signaling 305 from the circuitry 300 coupled with the portion 415-c may activate the second pair of selection transistors 410-b (e.g., and deactivate the first pair of selection transistors 410-a) to couple the via portion 425-c (e.g., and thus the via 420-a) with the one or more second output nodes 445. The analog blocks 430 may receive output signaling from the first output node 440 (e.g., coupled with the reference via 435) and the one or more second output nodes 445 of the portion 415-c, and may determine failure information associated with the via 420-a based on the output signaling.

For example, the analog blocks 430 may compare the output signaling from the first output node 440 and the output signaling from the one or more second output nodes 445 to determine real time failure information associated with the one or more vias. For example, if the output signaling received from the one or more second output nodes 445 is different than (e.g., less than) the output signaling from the first output node 440 by more than a threshold difference (e.g., a threshold voltage, a threshold current), the via 420 that is being tested may differ from the reference via, which may indicate a failing via. That is, a resistance associated with the via 420 may be higher than a reference resistance of the reference via. Thus, the analog blocks 430 may determine that the via 420 is a failing via (e.g., broken, malformed, containing deformities). Alternatively, if the output signaling received from the one or more second output nodes 445 is within the threshold difference of the output signaling from the first output node 440, the via not be defective.

Based on the shift registers 310, the circuitry 300 may subsequently (e.g., and in a similar manner) route the test signaling through the via 420-b, using pairs of selection transistors 410 coupled with the via 420-b. Accordingly, the circuitry 300 may use the circuitry 400 to route the test signaling (e.g., perform a test) through each via 420 in the memory system. Additionally, or alternatively, the circuitry 300 may activate a source transistor 405 and a first pair of selection transistors 410 of a different portion 415 (e.g., the portion 415-b) associated with a different memory die to route signaling through different via portions 425 of each via 420 (e.g., via portion 425-c), which may allow the memory system to determine a via portion 425 that is failing (e.g., as described with respect to FIGS. 5A and 5B).

FIGS. 5A and 5B show examples of circuitry portions 500 (e.g., portions of the third circuitry, failure information circuitry, circuitry portion 500-a, circuitry portion 500-b, circuitry portion 500-c, circuitry portion 500-d, and circuitry portion 500-e) that support methods and circuits for testing TSVs in accordance with examples as disclosed herein. In some cases, aspects of the circuitry portions 500 may implement or be implemented by aspects of FIGS. 1-4. For example, the circuitry portions 500 may be included in or coupled with the analog blocks 430. The circuitry portions 500 may determine and output failure information associated with the vias 420, as described herein with respect to FIGS. 1-4. In some aspects, FIGS. 5A and 5B may show one or more exemplary circuitry portions 500 that may receive one or more signals (e.g., from the analog blocks 430, from one or more clocks, from other sources or nodes described with respect to FIG. 6) and may determine, output, and/or store failure information (e.g., real time failure information) associated with the vias (e.g., TSVs) of a memory system based on the received one or more signals. That is, the third circuitry may include one or more of the circuitry portions 500 to determine, output, and/or store failure information associated with the vias.

As described with respect to FIG. 4, the analog blocks 430 (e.g., of the third circuitry) may be coupled with the memory dies of the memory system (e.g., including the bottom memory die) and may be configured to receive the output signaling from the memory dies (e.g., from the first output node 440 and the one or more second output nodes 445). The output signaling may be based on the test signaling (e.g., an output of the test signaling from a tested via). In some cases, the analog blocks 430 may compare the output signaling to determine and output real time failure information associated with the vias (e.g., the Pass signal described with respect to FIG. 6), and the circuitry portions 500 may be configured to receive the real time failure information and determine, output, and/or store other failure information associated with the vias of the memory system.

In some cases, the circuitry portion 500-a may output failure information, including real time failure indications (e.g., Fail_P), associated with the plurality of vias. For example, by receiving (e.g., monitoring) the Pass signal from the analog block 430, the circuitry portion 500-a may obtain and output real time pass or fail information associated with the testing of individual vias of the memory system. For example, Fail_P may be a real time signal capable of indicating whether a via failed a respective testing operation. In some cases, the circuitry portion 500-a may also determine Cnt_Val <m:0>, which may be a counter value driven by Ck_Tsv_Counter (e.g., further described with respect to FIG. 6) and indicates location information associated with a via that is being tested at a current time (e.g., further described with respect to circuitry portion 500-d and FIG. 6).

To determine the value of Fail_P, Cnt_Val <m:0>, or both, the circuitry portion 500-a may receive one or more signals. For example, the circuitry portion 500-a may receive real time failure indications (e.g., the Pass signal), TmTsvTestStart, N_EnF (e.g., further described with respect to circuitry portion 500-e), Ck_Tsv_Test, and Ck_Pass, which may be further described herein with respect to FIGS. 3 and 6. The circuitry portion 500-a may include one or more logical components and sub-circuits (e.g., NANDs, NOTs, DFFs, latches (LATs), delay components (DLYs)) to generate Fail_P and Cnt_Val <m:0> based on the received one or more signals.

In some cases, the circuitry portion 500-b may output failure information that indicates whether the vias of the memory system include at least one failing via. For example, TSV_Fail_Out may transition from low to high if the Fail_P signal is high while testing the vias of the memory system (e.g., further described with respect to FIG. 6). Thus, the memory system may read the TSV_Fail_Out signal after performing testing on multiple vias in the memory system to determine whether a failure occurred within the vias. That is, the TSV_Fail_Out may indicate whether the vias of the memory system include any failing vias, where a failing via may be a via associated with a resistance that is above a threshold resistance or different from a resistance of a reference via by a threshold amount (e.g., as determined by the comparison of output signaling by the analog blocks). In some cases, the circuitry portion 500-b may determine whether the vias include a failing via based on receiving Fail_P at a shift register 510, which may couple a high voltage (e.g., VDD) with the TSV_Fail_Out signal if Fail_P transitions to a high value.

In some cases, the circuitry portion 500-c may output failure information that indicates a quantity of failing vias of the plurality of vias. For example, TSV_Fail_Number <m:0> may indicate a count value driven by Fail_P, where the memory system may read TSV_Fail_Number <m:0> after testing multiple vias to determine the quantity of vias of the multiple vias that are failing vias. For example, the circuitry portion 500-c may receive Fail_P at a counter, which may update TSV_Fail_Number <m:0> to indicate a TSV Fail Count as part of the failure information (e.g., as described herein with respect to FIG. 6).

In some cases, the circuitry portion 500-d may output failure information that indicates whether one or more vias (e.g., one or more indices of one or more failing vias) of are failing or otherwise defective. For example, each via may be associated with an index (e.g., y, as described with respect to FIGS. 3 and 4). The Cnt_Val <m:0> may indicate the index of a via being tested, and the circuitry portion 500-d may store the value of Cnt_Val <m:0> if Fail_P transitions to a high value (e.g., as described with respect to FIG. 6). For example, the circuitry portion 500-d may store the index of any quantity of vias in locations referred to as TSV_Fail_Add_z <m:0>, where z may be any identifier for the location. For example, circuitry portion 500-d may illustrate a memory system with the capacity to store the indices of two vias, for example, in TSV_Fail_Add_E <m:0>0 and TSV_Fail_Add_O <m:0>. Each location TSV_Fail_Add_z <m:0> may be coupled with a shift register 510 that receives a fail signal referred to as Fail_P_z (e.g., Fail_P_E and Fail_P_O, for example, as described with respect to FIG. 6). When Fail_P_z transitions to a high value, the corresponding shift register 510 may couple the Cnt_Val <m:0> signal with TSV_Fail_Add_z <m:0> to store the index of the via that caused Fail_P_z to transition to the high value.

In some cases, the circuitry portion 500-e may output failure information that indicates when the multiple vias (e.g., all of the multiple vias) of the memory system have been tested. That is, circuitry portion 500-e may output N_EnF, where N_EnF may be set to a first value (e.g., a high value) by default, and may transition to a second value (e.g., a low value) if the value of Cnt_Val <m:0> equals the quantity of the multiple vias of the memory system (e.g., all of the vias of the memory system). For example, the circuitry portion 500-e may include one or more switches 515 and one or more logical components 520 (e.g., XNORs), where the logical components 520 may receive, as inputs, a bit Cnt_Val <n> from the Cnt_Val <m:0> (e.g., in the case of a nine bit Cnt_Val <m:0>, 0≤n≤8) and either a relatively high voltage (e.g., VDD) or a relatively low voltage (e.g., VSS, ground) based on a position of a corresponding switch 515. The positions of the switches may be based on a total quantity of the vias of the memory system (e.g., or a smaller quantity, for testing subsets of vias), such that when the bit values of Cnt_Val <m:0> indicate the total quantity (e.g., or the smaller quantity), N_EnF may transition to the second value (e.g., the low value) based on the circuitry portion 500-e. In some cases, the memory system may stop testing vias based on N_EnF transitioning to the second value (e.g., as described with respect to FIG. 6).

Thus, the third circuitry may include one or more of the circuitry portions 500 to determine, output, and/or store failure information associated with the one or more vias of the memory system. As used herein, the high value and low value may be arbitrary and different for each signal, and the low value may be higher than the high value, or vice versa.

FIG. 6 shows an example of a timing diagram 600 that supports methods and circuits for testing TSVs in accordance with examples as disclosed herein. In some cases, aspects of the timing diagram 600 may implement or be implemented by aspects of FIGS. 1-5. For example, the timing diagram 600 may illustrate one or more signals, which may include one or more signals as described herein with respect to FIGS. 1-5 (e.g., the signaling 320, activation signaling 305, signals received or outputted from the circuitry portions 500). In some aspects, the timing diagram 600 may illustrate correlated timing of the one or more signals associated with testing the vias of a memory system between a first memory die (e.g., an upper memory die for via testing, a top memory die, a memory die below the top memory die) and a second memory die (e.g., a bottom memory die, a memory die above the bottom memory die). The signals in the timing diagram 600 may also be associated with determining, outputting, or storing failure information associated with the vias of a memory system. Some of the signals of the timing diagram 600 (e.g., the activation signals 305) may be illustrated as being associated with the first memory die in the memory system (e.g., a bottom die, memory die 0), but the techniques described with respect to the timing diagram 600 may be applicable to any or all memory dies in the memory system.

The timing diagram 600 may include a clock signal Clk, which may be an internal or external clock signal associated with the memory system. The timing diagram 600 may also include TmTsvTestEn, which may be an enable signal for the Ck_Tsv_Test signal (e.g., as described with respect to FIG. 3). That is, when the memory system sets TmTsvTestEn to the high value, Ck_Tsv_Test may begin toggling in sync with Clk. The timing diagram 600 may also include TmTsvTestStart, which may be a signal to initiate the generation of sequential pulses by the one or more shift registers 310 of circuitry 300 (e.g., as described with respect to FIG. 3). In some cases, Clk and Ck_Tsv_Test may continue a regular clock cycle throughout the testing of the vias, and TmTsvTestEn and TmTsvTestStart may maintain a fixed value (e.g., a high value) throughout the testing of the vias after being activated.

Based on the sequential pulse generation of the shift registers 310 (e.g., not shown in the timing diagram 600), the circuitry 300 may activate activation signals 305 sequentially. For example, a time 605, the circuitry 300 of the second memory die may set Tsv_TestEn_R0_0 to high (e.g., based on the signaling received from the controller and the shift register pulses, described with respect to FIG. 3), and the circuitry 300 of the first memory die may set and Tsv_TestEn_Ri_0 (e.g., where i may be the index of the first memory die) to high, which may route test signaling through a first via of the memory system from a test signaling source (e.g., a source transistor 405 coupled with the first memory die, as described with respect to FIG. 4). Additionally, Ck_Tsv_Counter may transition to a high state for at least a portion of a clock cycle of Clk based on Tsv_TestEn_R0_0 and Tsv_TestEn_Ri_0 being set to the high value. For example, Ck_Tsv_Counter may toggle high for each via being tested (e.g., for each Tsv_TestEn_Rx_y and Tsv_TestEn_Ri_y that are set to a high value). In some cases, Ck_Tsv_Counter may begin toggling between the high and low values one clock cycle of Clk after TmTsvTestStart transitions to the high value.

Additionally, at time 605 and based on Ck_Tsv_Counter transitioning to a high value, Cnt_Val <m:0> may count up by one (e.g., starting at 0 when TmTsvTestStart toggles from the low value to the high value). For example, Cnt_Val <m:0> may count the quantity of vias that have been tested based on the Ck_Tsv_Counter, as described with respect to the circuitry portion 500-a. That is, each time that Ck_Tsv_Counter transitions to the high value, Cnt_Val <m:0> may count up by one.

Based on the sequential pulse generation of the shift registers 310, at time 610, the circuitry 300 of the second memory die and the first memory die may set Tsv_TestEn_R0_0 and Tsv_TestEn_Ri_0, respectively, to a low value, and may set next activation signals 305 to the high value (e.g., such as Tsv_TestEn_R0_1 and Tsv_TestEn_Ri_1). Setting Tsv_TestEn_R0_1 and Tsv_TestEn_Ri_1 to the high value may begin the testing of a second via of the memory system. Accordingly, Ck_Tsv_Counter may toggle to the high value and Cnt_Val <m:0> may count up by one. The sequential pulse generation of the shift registers 310 may cause the sequential testing of N vias included in the memory system, where N may be a positive integer. For example, at time 635, the circuitry 300 may set Tsv_TestEn_R0_N and Tsv_TestEn_Ri_N to high to test an N^{th} (e.g., a last) via of the memory system. As described with respect to FIG. 5B, Cnt_Val <m:0>may reach N at time 635 based on the Ck_Tsv_Counter toggling, and N_EnF may transition from a first value (e.g., a high value) to a second value (e.g., a low value). Based on the transition of N_EnF, the circuitry 300 may stop setting activation signals 305 to the high value, and Ck_Tsv_Counter may stop toggling (e.g., based on circuitry portion 500-e).

At time 605, based on routing the test signaling through the first via, the analog blocks 430 may compare the output signaling and determine if the first via is a failing via or a passing via (e.g., based on a threshold difference between a voltage or current output between the reference via and the first via). The Pass signal may be an output of the comparison (e.g., output from an analog comparator of the analog blocks 430). For example, the Pass signal may end each clock cycle at a first value or a second value, where the first value (e.g., a high value) may represent a passing via, and a second value (e.g., a low value) may represent a failing via. At time 610 (e.g., when a second via begins to be tested, one clock cycle of Clk after time 605), the Ck_Pass clock signal may toggle high based on the first via being tested at 605. That is, the Ck_Pass clock signal may toggle one clock cycle of Clk behind (e.g., slower) than Ck_Tsv_Counter.

At 610, a second via of the memory system may begin to be tested. Based on the comparison at the analog blocks 430, the Pass signal may be set to the low value between time 610 and time 615, indicating that the second via is a failing via. Accordingly, at 615 (e.g., based on the one clock cycle lag of Ck_Pass compared to Ck_Tsv_Counter), Fail_P may transition to a high value to indicate the failing second via, and may transition back to a low value before time 620 (e.g., based on the circuitry portion 500-a). That is, when the memory system captures the second value of the Pass signal and Ck_Pass, Fail_P may be set to the high value (e.g., based on the circuitry portion 500-a). At time 615, based on Fail_P transitioning to the high value, TSV_Fail_Out may transition to the high value to indicate that the vias of the memory system include at least one failing via (e.g., based on the circuitry portion 500-b), and the TSV_Fail_Number <m:0> may count up by one integer to count the quantity of failing vias within the vias of the memory system (e.g., based on the circuitry portion 500-c). Additionally, or alternatively, at time 615 and based on Fail_P transitioning to the high value, Fail_P_E (e.g., or a first Fail_P_z value) may transition to a high value to store the index of the failed via (e.g., as stored by Cnt_Val <m:0> prior to counting up one integer at time 615) in the location TSV_Fail_Add_E (e.g., e.g., the location TSV_Fail_Add_z corresponding to the first Fail_P_z, as described with respect to FIG. 5B and circuitry portion 500-d).

As described herein, the sequential pulse generation of the shift registers 310 may cause the testing of each via of the memory system. For example, at time 630, the circuitry 300 may set Tsv_TestEn_R0_N−1 and Tsv_TestEn_Ri_N−1 to the high value, which may route the test signaling through the N−1^{th} via of the memory system (e.g., beginning the testing of the N−1^{th} via). In some cases, the comparison at the analog blocks 430 may determine that the N−1^{th} via is a failing via, which may cause the Pass signal to transition to the low value between time 630 and time 635. Based on the transition of the Pass signal to the low value, Fail_P may transition to the high value at time 635, which may cause TSV_Fail_Number <m:0> to increase by one integer (e.g., to two), and may cause Fail_P_O (e.g., a second Fail_P_z) to transition to the high value. Based on Fail_P_O transitioning to the high value, the location TSV_Fail_Add_O (e.g., the location TSV_Fail_Add_z corresponding to the second Fail_P_z, as described with respect to FIG. 5B and circuitry portion 500-d) may store the index of the failing via (e.g., N−1) as indicated by Cnt_Val <m:0>(e.g., prior to counting up by one integer at 635). The memory system may begin testing the N^{th} via at time 635, causing Cnt_Val <m:0>to reach N, causing N_EnF to transition to the low value, and stopping the via testing.

Accordingly, the memory system may utilize the circuitry 300, the circuitry 400, and the circuitry portions 500 to route test signaling through each via of the memory system and determine, indicate, and/or store failure information associated with the vias of the memory system. Based on the failure information, the memory system may be altered, utilized, or discarded, to provide a more reliable memory system and reduce errors caused by failing vias.

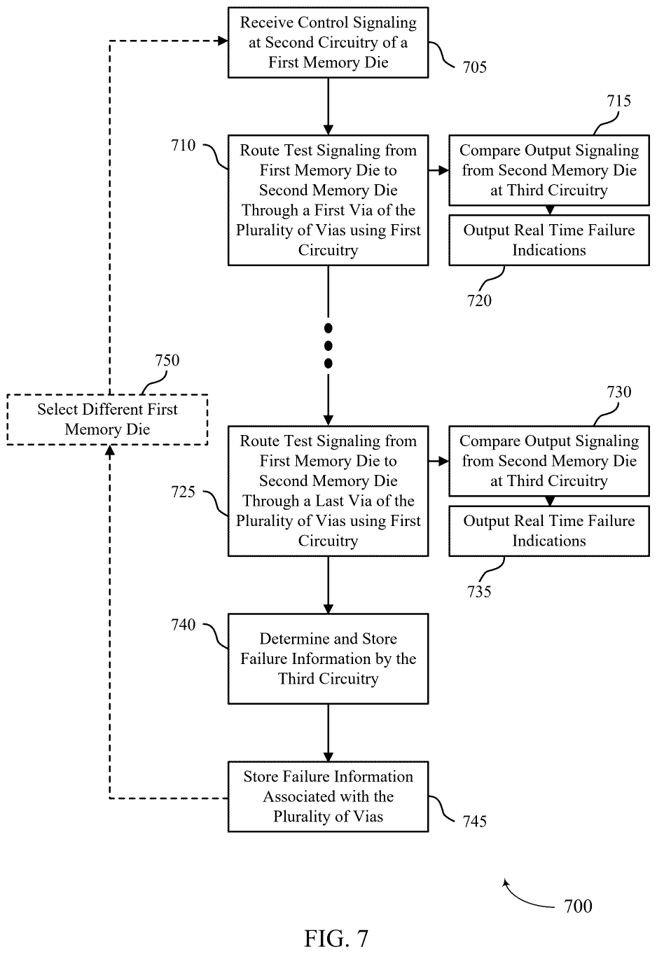

FIG. 7 shows an example of a flow chart 700 that supports methods and circuits for testing TSVs in accordance with examples as disclosed herein. In some cases, aspects of the flow chart 700 may implement or be implemented by aspects of FIGS. 1-6. For example, the flow chart 700 may illustrate aspects of a method used to test vias in a memory system, which may be implemented by circuitry and signaling described herein with respect to FIGS. 1-6.

In the following description of the flow chart 700, the operations may be performed in a different order than the order shown, or other operations may be added or removed from the flow chart 700. For example, some operations may be left out of the flow chart 700, may be performed in different orders or at different times, or other operations may be added to the flow chart 700. Although the circuitry 300, 400, and 500 may assist in performing one or more of the operations of flow chart 700, some aspects of some operations may also be performed using one or more other aspects of a memory system, such as those described with respect to FIGS. 1 and 2.

At 705, the circuitry 300 of the memory dies of the memory system (e.g., stack of memory dies) may receive signaling (e.g., the signaling 320), where each memory die of the memory system may include a portion 415 of circuitry 400 that may be coupled with a one or more vias (e.g., or via portions 425) and circuitry 300 that receives the signaling. In some cases, the one or more vias may extend through the memory dies of the memory system and may route signaling between at least a first memory die of the memory system and a second memory die of the memory system. In some cases, the signaling 320 received at the circuitry 300 of a respective memory die may include an indication of the respective memory die, an indication of the first memory die, a shift register start signal, source connection transistor activation signaling, or any combination thereof (e.g., as described herein with respect to FIG. 3).

At 710, the memory system (e.g., the circuitry 300) may route, using the circuitry 400, test signaling between the first memory die and the second memory die through a via of the one or more vias based on receiving the signaling at the circuitry 300. In some cases, the circuitry 300 may use the circuitry 400 to route the test signaling from the first memory die to a first output node of the second memory die through a reference via that is coupled with the first output node (e.g., as described with respect to FIG. 4). Additionally, or alternatively, the circuitry 300 may use the circuitry 400 to route the test signaling from the first memory die to a second output node of the second memory die through the via of the one or more vias, wherein the first output node and the second output node may be associated with the output signaling received at the analog blocks (e.g., as described with respect to FIGS. 4-7, as part of the third circuitry, where the third circuitry may include the analog blocks 430 and one or more of the circuitry portions 500).

At 715, the third circuitry (e.g., including the analog blocks 430, one or more of the circuitry portions 500, or any combination thereof) may receive and compare output signaling from the first output node and the second output node of the second memory die. For example, the circuitry 400 may route the test signaling though the reference via to the first output node to be outputted as output signaling, and the circuitry 400 may route the test signaling through the via of the one or more vias to the second output node to be outputted as output signaling. At 720, based on the third circuitry receiving the output signaling from the second memory die and comparing the output signaling associated with the reference via to the output signaling associated with the tested via, the third circuitry (e.g., the analog blocks 430, one or more of the circuitry portions 500) may output real time failure indications (e.g., Fail_P, described with respect to FIGS. 5A-6) associated with the one or more vias.

The circuitry 300 may use the circuitry 400 (e.g., via the activation signals 305) to route the test signaling through each via of the one or more vias of the memory system. For example, at 725, the circuitry 300 may use the circuitry 400 to route the test signaling from the first memory die to the second memory die through a last via (e.g., an N^{th} via, where N is a total quantity of the one or more vias, or a smaller quantity based on testing a subset of the one or more vias) of the one or more vias based on one or more shift registers of the circuitry 300. At 730 and 735, the third circuitry may receive the output signaling associated with the last via from the second memory die and may output real time failure indications associated with the last via (e.g., similar to the operations described at 715 and 720).

At 740, the third circuitry may determine and store failure information (e.g., in memory of the memory system) based on the real time failure information. For example, the failure information associated with the one or more vias may indicate whether the plurality of vias includes a failing via, a via (e.g., an index of a via) of the one or more vias that is a failing via, a quantity of failing vias of the one or more vias, or any combination thereof (e.g., as described with respect to FIGS. 4-6) . Additionally, or alternatively, the third circuitry may receive a counter value (e.g., Ck_Tsv_Counter, Cnt_Val <m:0>, as described with respect to FIGS. 4-6) associated with the real time failure indications associated with the one or more vias, where the failure information associated with the one or more vias may be further based on the counter value. In some cases, the failure information may also be based on routing the test signaling through each via of the one or more vias.

At 745, the third circuitry may store the failure information associated with the one or more vias based on the output signaling from the second memory die. In some cases, the memory system may receive the failure information or read the failure information from one or more registers or memory of the memory system. In some cases, the failure information may indicate a failure associated with the one or more vias (e.g., one or more failing vias). For example, at 750, based on the failure information indicating one or more failures associated with the one or more vias, the circuitry 300 may use the circuitry 400 to select a different memory die of the memory system (e.g., of the stack of memory dies) to be the first memory die (e.g., the upper memory die for via testing), which may not be a top memory die of the memory system. For example, the circuitry 300 may receive second signaling indicating a third memory die of the memory system (e.g., in place of the first memory die).

According to the operations of 710 through 745, the circuitry 300 may use the circuitry 400 to route second test signaling from the third memory die to the second memory die through one or more via portion of the via (e.g., as described with respect to FIG. 4) based on the second signaling, and the third circuitry (e.g., including one or more of the circuitry portions 500) may determine, output, or store failure information associated with the one or more via portions of each of the one or more vias based on second output signaling from the second memory die (e.g., where the second output signaling may be based on the second test signaling). Thus, the memory system may utilize the circuity and signals described with respect to FIGS. 3-6 to test one or more vias or via portions and determine, output, or store (e.g., or any combination thereof) failure information associated with the one or more vias of via portions.

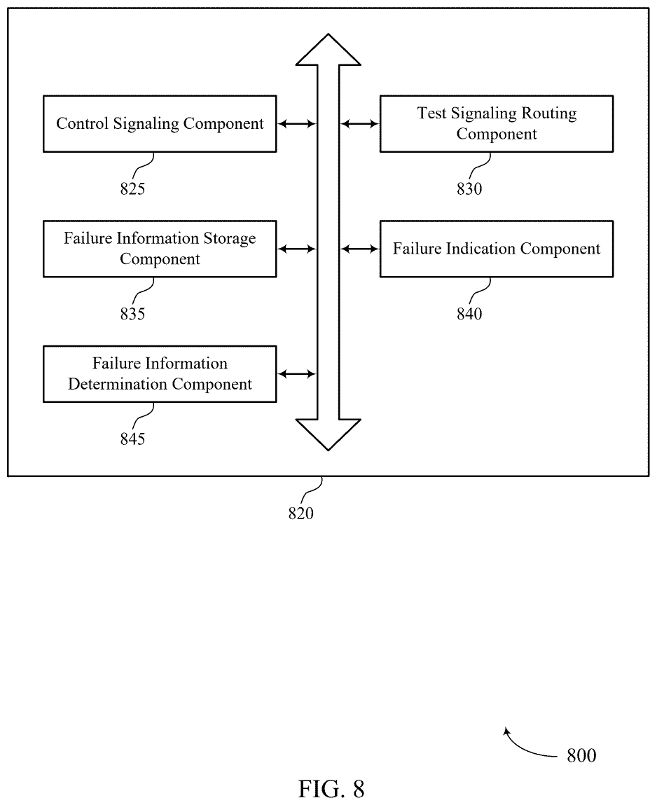

FIG. 8 shows a block diagram 800 of a memory system 820 that supports methods and circuits for testing TSVs in accordance with examples as disclosed herein. The memory system 820 may be an example of aspects of a memory system as described with reference to FIGS. 1 through 6. The memory system 820, or various components thereof, may be an example of means for performing various aspects of methods and circuits for testing TSVs as described herein. For example, the memory system 820 may include a control signaling component 825, a test signaling routing component 830, a failure information storage component 835, a failure indication component 840, a failure information determination component 845, or any combination thereof. Each of these components, or components of subcomponents thereof (e.g., one or more processors, one or more memories), may communicate, directly or indirectly, with one another (e.g., via one or more buses).

The control signaling component 825 may be configured as or otherwise support a means for receiving control signaling by at least one memory die of a stack of memory dies of the memory system, where each memory die of the stack of memory dies includes first circuitry coupled with a plurality of vias and second circuitry that receives the control signaling, where the plurality of vias extend through the stack of memory dies and route signaling between at least a first memory die of the stack of memory dies and a second memory die of the stack of memory dies. The test signaling routing component 830 may be configured as or otherwise support a means for routing, using the first circuitry, test signaling between the first memory die and the second memory die through a via of the plurality of vias based at least in part on receiving the control signaling. The failure information storage component 835 may be configured as or otherwise support a means for storing, by third circuitry that is coupled with the second memory die, failure information associated with the plurality of vias based at least in part on output signaling from the second memory die, where the output signaling is based at least in part on routing the test signaling between the first memory die and the second memory die.

In some examples, to support routing the test signaling from the first memory die to the second memory die, the test signaling routing component 830 may be configured as or otherwise support a means for routing the test signaling from the first memory die to a first node of the second memory die through a reference via that is coupled with the first node. In some examples, to support routing the test signaling from the first memory die to the second memory die, the test signaling routing component 830 may be configured as or otherwise support a means for routing the test signaling from the first memory die to a second node of the second memory die through the via of the plurality of vias, where the first node and the second node are associated with the output signaling.

In some examples, the failure information determination component 845 may be configured as or otherwise support a means for comparing the output signaling from the first node to the output signaling from the second node to determine the failure information.

In some examples, the test signaling routing component 830 may be configured as or otherwise support a means for routing the test signaling from the first memory die to the second memory die through each via of the plurality of vias based at least in part on a plurality of shift registers of the second circuitry, where the failure information is based at least in part on routing the test signaling through each via.

In some examples, the failure information associated with the plurality of vias indicates whether the plurality of vias includes a failing via, whether a second via of the plurality of vias that is a failing via, whether a quantity of failing vias of the plurality of vias, or any combination thereof.

In some examples, the control signaling received at the second circuitry of a respective memory die includes an indication of a respective memory die of the stack of memory dies, an indication of the first memory die of the stack of memory dies, a shift register start signal, source connection transistor activation signaling, or any combination thereof.

In some examples, the failure indication component 840 may be configured as or otherwise support a means for outputting, by the third circuitry, real time failure indications associated with the plurality of vias based at least in part on the output signaling.

In some examples, the failure information determination component 845 may be configured as or otherwise support a means for receiving, at the third circuitry, a counter value associated with the real time failure indications associated with the plurality of vias, where the failure information associated with the plurality of vias is further based at least in part on the counter value.

In some examples, the failure information indicates a failure associated with the plurality of vias, and the control signaling component 825 may be configured as or otherwise support a means for receiving, at the second circuitry, second control signaling indicating a third memory die of the stack of memory dies based at least in part on the failure associated with the plurality of vias. In some examples, the failure information indicates a failure associated with the plurality of vias, and the test signaling routing component 830 may be configured as or otherwise support a means for routing, using the first circuitry, second test signaling from the third memory die to the second memory die through a portion of the via based at least in part on the second control signaling. In some examples, the failure information indicates a failure associated with the plurality of vias, and the failure information storage component 835 may be configured as or otherwise support a means for storing, by the third circuitry, failure information associated with the portion of each of the plurality of vias based at least in part on second output signaling from the second memory die, where the second output signaling is based at least in part on the second test signaling.

In some examples, the described functionality of the memory system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 820, or various components thereof, may be implemented at least in part by instructions (e.g., stored in memory, non-transitory computer-readable medium) executable by such at least one processor.

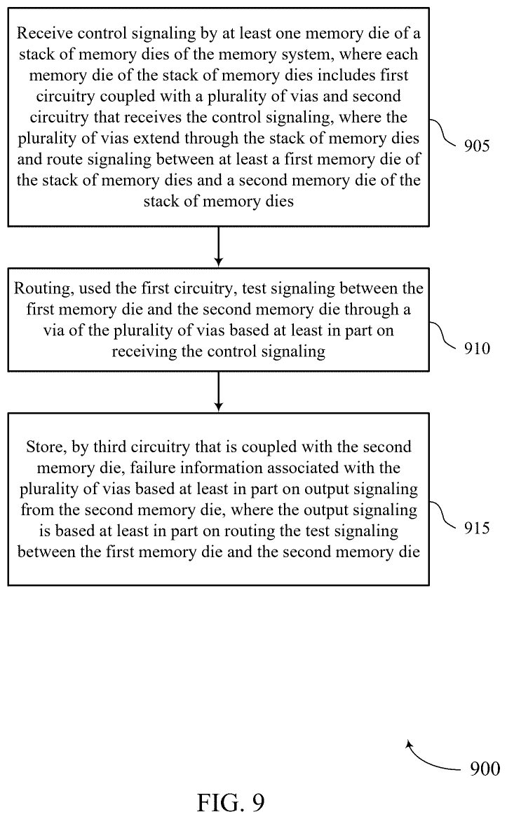

FIG. 9 shows a flowchart illustrating a method 900 that supports methods and circuits for testing TSVs in accordance with examples as disclosed herein. The operations of method 900 may be implemented by a memory system or its components as described herein. For example, the operations of method 900 may be performed by a memory system as described with reference to FIGS. 1 through 8. In some examples, a memory system may execute a set of instructions to control the functional elements of the device to perform the described functions. Additionally, or alternatively, the memory system may perform aspects of the described functions using special-purpose hardware.

At 905, the method may include receiving control signaling by at least one memory die of a stack of memory dies of the memory system, where each memory die of the stack of memory dies includes first circuitry coupled with a plurality of vias and second circuitry that receives the control signaling, where the plurality of vias extend through the stack of memory dies and route signaling between at least a first memory die of the stack of memory dies and a second memory die of the stack of memory dies. In some examples, aspects of the operations of 905 may be performed by a control signaling component 825 as described with reference to FIG. 8.

At 910, the method may include routing, using the first circuitry, test signaling between the first memory die and the second memory die through a via of the plurality of vias based at least in part on receiving the control signaling. In some examples, aspects of the operations of 910 may be performed by a test signaling routing component 830 as described with reference to FIG. 8.

At 915, the method may include storing, by third circuitry that is coupled with the second memory die, failure information associated with the plurality of vias based at least in part on output signaling from the second memory die, where the output signaling is based at least in part on routing the test signaling between the first memory die and the second memory die. In some examples, aspects of the operations of 915 may be performed by a failure information storage component 835 as described with reference to FIG. 8.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving control signaling by at least one memory die of a stack of memory dies of the memory system, where each memory die of the stack of memory dies includes first circuitry coupled with a plurality of vias and second circuitry that receives the control signaling, where the plurality of vias extend through the stack of memory dies and route signaling between at least a first memory die of the stack of memory dies and a second memory die of the stack of memory dies; routing, using the first circuitry, test signaling between the first memory die and the second memory die through a via of the plurality of vias based at least in part on receiving the control signaling; and storing, by third circuitry that is coupled with the second memory die, failure information associated with the plurality of vias based at least in part on output signaling from the second memory die, where the output signaling is based at least in part on routing the test signaling between the first memory die and the second memory die.

Aspect 2: The method, apparatus, or non-transitory computer-readable medium of aspect 1, where routing the test signaling from the first memory die to the second memory die includes operations, features, circuitry, logic, means, or instructions, or any combination thereof for routing the test signaling from the first memory die to a first node of the second memory die through a reference via that is coupled with the first node and routing the test signaling from the first memory die to a second node of the second memory die through the via of the plurality of vias, where the first node and the second node are associated with the output signaling.

Aspect 3: The method, apparatus, or non-transitory computer-readable medium of aspect 2, further including operations, features, circuitry, logic, means, or instructions, or any combination thereof for comparing the output signaling from the first node to the output signaling from the second node to determine the failure information.

Aspect 4: The method, apparatus, or non-transitory computer-readable medium of any of aspects 1 through 3, further including operations, features, circuitry, logic, means, or instructions, or any combination thereof for routing the test signaling from the first memory die to the second memory die through each via of the plurality of vias based at least in part on a plurality of shift registers of the second circuitry, where the failure information is based at least in part on routing the test signaling through each via.

Aspect 5: The method, apparatus, or non-transitory computer-readable medium of any of aspects 1 through 4, where the failure information associated with the plurality of vias indicates whether the plurality of vias includes a failing via, whether a second via of the plurality of vias that is a failing via, whether a quantity of failing vias of the plurality of vias, or any combination thereof.

Aspect 6: The method, apparatus, or non-transitory computer-readable medium of any of aspects 1 through 5, where the control signaling received at the second circuitry of a respective memory die includes an indication of a respective memory die of the stack of memory dies, an indication of the first memory die of the stack of memory dies, a shift register start signal, source connection transistor activation signaling, or any combination thereof.

Aspect 7: The method, apparatus, or non-transitory computer-readable medium of any of aspects 1 through 6, further including operations, features, circuitry, logic, means, or instructions, or any combination thereof for outputting, by the third circuitry, real time failure indications associated with the plurality of vias based at least in part on the output signaling.

Aspect 8: The method, apparatus, or non-transitory computer-readable medium of aspect 7, further including operations, features, circuitry, logic, means, or instructions, or any combination thereof for receiving, at the third circuitry, a counter value associated with the real time failure indications associated with the plurality of vias, where the failure information associated with the plurality of vias is further based at least in part on the counter value.

Aspect 9: The method, apparatus, or non-transitory computer-readable medium of any of aspects 1 through 8, where the failure information indicates a failure associated with the plurality of vias and the method, apparatuses, and non-transitory computer-readable medium further includes operations, features, circuitry, logic, means, or instructions, or any combination thereof for receiving, at the second circuitry, second control signaling indicating a third memory die of the stack of memory dies based at least in part on the failure associated with the plurality of vias; routing, using the first circuitry, second test signaling from the third memory die to the second memory die through a portion of the via based at least in part on the second control signaling; and storing, by the third circuitry, failure information associated with the portion of each of the plurality of vias based at least in part on second output signaling from the second memory die, where the second output signaling is based at least in part on the second test signaling.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: a stack of memory dies including a plurality of vias and first circuitry coupled with the plurality of vias, where the plurality of vias extend through the stack of memory dies and are configured to route signaling between at least a first memory die of the stack of memory dies and a second memory die of the stack of memory dies; second circuitry in each memory die of the stack of memory dies, where the second circuitry of each memory die is coupled with the first circuitry, the second circuitry configured to receive signaling to use the first circuitry to route test signaling between the first memory die and the second memory die through a via of the plurality of vias; and third circuitry coupled with the second memory die and configured to receive output signaling from the second memory die that is based at least in part on the test signaling, where the third circuitry is configured to store failure information associated with the plurality of vias based at least in part on the output signaling.

Aspect 11: The apparatus of aspect 10, where: the first circuitry of the first memory die includes: a transistor including a first node coupled with a source of the test signaling; and a first pair of transistors that selectively couple a second node of the transistor with the via and selectively couples the second node of the transistor with a reference via, where the reference via is coupled with a first output node of the second memory die; and the first circuitry of the second memory die includes: a second pair of transistors that selectively couple the via with a second output node of the second memory die, where the third circuitry receives the output signaling from the first output node and the second output node.

Aspect 12: The apparatus of aspect 11, where the third circuitry is configured to compare the output signaling from the first output node and the output signaling from the second output node, and the failure information is based at least in part on comparing the output signaling from the first output node and the output signaling from the second output node.

Aspect 13: The apparatus of any of aspects 10 through 12, where the second circuitry includes: a plurality of shift registers that route, based at least in part on the signaling, the test signaling from the first memory die to the second memory die through each via of the plurality of vias, where the failure information is based at least in part on the test signaling being routed through each via.

Aspect 14: The apparatus of any of aspects 10 through 13, where the failure information associated with the plurality of vias indicates whether the plurality of vias includes a failing via, a second via of the plurality of vias that is a failing via, a quantity of failing vias of the plurality of vias, or any combination thereof.

Aspect 15: The apparatus of any of aspects 10 through 14, where the signaling received by the second circuitry of a respective memory die includes an indication of a respective memory die of the stack of memory dies, an indication of the first memory die of the stack of memory dies, a shift register start signal, source connection transistor activation signaling, or any combination thereof.

Aspect 16: The apparatus of any of aspects 10 through 15, where the third circuitry is further configured to output real time failure indications associated with the plurality of vias based at least in part on the output signaling.

Aspect 17: The apparatus of aspect 16, where the third circuitry is configured to receive signaling associated with the real time failure indications, the failure information associated with the plurality of vias is based at least in part on the signaling.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a stack of memory dies comprising a plurality of vias and first circuitry coupled with the plurality of vias, wherein the plurality of vias extend through the stack of memory dies and are configured to route signaling between at least a first memory die of the stack of memory dies and a second memory die of the stack of memory dies;
second circuitry in each memory die of the stack of memory dies, wherein the second circuitry of each memory die is coupled with the first circuitry, the second circuitry configured to receive signaling to use the first circuitry to route test signaling between the first memory die and the second memory die through a via of the plurality of vias; and
third circuitry coupled with the second memory die and configured to receive output signaling from the second memory die that is based at least in part on the test signaling, wherein the third circuitry is configured to store failure information associated with the plurality of vias based at least in part on the output signaling.

2. The apparatus of claim 1, wherein:
the first circuitry of the first memory die comprises:
a transistor comprising a first node coupled with a source of the test signaling; and
a first pair of transistors that selectively couple a second node of the transistor with the via and selectively couples the second node of the transistor with a reference via, wherein the reference via is coupled with a first output node of the second memory die; and
the first circuitry of the second memory die comprises:
a second pair of transistors that selectively couple the via with a second output node of the second memory die, wherein the third circuitry receives the output signaling from the first output node and the second output node.

3. The apparatus of claim 2, wherein:
the third circuitry is configured to compare the output signaling from the first output node and the output signaling from the second output node, and
the failure information is based at least in part on comparing the output signaling from the first output node and the output signaling from the second output node.

4. The apparatus of claim 1, wherein the second circuitry comprises:
a plurality of shift registers that route, based at least in part on the signaling, the test signaling from the first memory die to the second memory die through each via of the plurality of vias, wherein the failure information is based at least in part on the test signaling being routed through each via.

5. The apparatus of claim 1, wherein the failure information associated with the plurality of vias indicates whether the plurality of vias comprises a failing via, a second via of the plurality of vias that is a failing via, a quantity of failing vias of the plurality of vias, or any combination thereof.

6. The apparatus of claim 1, wherein the signaling received by the second circuitry of a respective memory die includes an indication of a respective memory die of the stack of memory dies, an indication of the first memory die of the stack of memory dies, a shift register start signal, source connection transistor activation signaling, or any combination thereof.

7. The apparatus of claim 1, wherein the third circuitry is further configured to output real time failure indications associated with the plurality of vias based at least in part on the output signaling.

8. The apparatus of claim 7, wherein:
the third circuitry is configured to receive signaling associated with the real time failure indications, and
the failure information associated with the plurality of vias is based at least in part on the signaling.

9. A memory system, comprising:
one or more memory devices; and
processing circuitry coupled with the one or more memory devices and configured to cause the memory system to:
receive control signaling by at least one memory die of a stack of memory dies of the memory system, wherein each memory die of the stack of memory dies comprises first circuitry coupled with a plurality of vias and second circuitry that receives the control signaling, wherein the plurality of vias extend through the stack of memory dies and route signaling between at least a first memory die of the stack of memory dies and a second memory die of the stack of memory dies;
routing, used the first circuitry, test signaling between the first memory die and the second memory die through a via of the plurality of vias based at least in part on receiving the control signaling; and
store, by third circuitry that is coupled with the second memory die, failure information associated with the plurality of vias based at least in part on output signaling from the second memory die, wherein the output signaling is based at least in part on routing the test signaling between the first memory die and the second memory die.

10. The memory system of claim 9, wherein routing the test signaling from the first memory die to the second memory die comprises the processing circuitry configured to cause the memory system to:
rout the test signaling from the first memory die to a first node of the second memory die through a reference via that is coupled with the first node; and
rout the test signaling from the first memory die to a second node of the second memory die through the via of the plurality of vias, wherein the first node and the second node are associated with the output signaling.

11. The memory system of claim 10, wherein the processing circuitry is further configured to cause the memory system to:
compare the output signaling from the first node to the output signaling from the second node to determine the failure information.

12. The memory system of claim 9, wherein the processing circuitry is further configured to cause the memory system to:
rout the test signaling from the first memory die to the second memory die through each via of the plurality of vias based at least in part on a plurality of shift registers of the second circuitry, wherein the failure information is based at least in part on routing the test signaling through each via.

13. The memory system of claim 9, wherein the failure information associated with the plurality of vias indicates whether the plurality of vias comprises a failing via, whether a second via of the plurality of vias that is a failing via, whether a quantity of failing vias of the plurality of vias, or any combination thereof.

14. The memory system of claim 9, wherein the control signaling received at the second circuitry of a respective memory die includes an indication of a respective memory die of the stack of memory dies, an indication of the first memory die of the stack of memory dies, a shift register start signal, source connection transistor activation signaling, or any combination thereof.

15. The memory system of claim 9, wherein the processing circuitry is further configured to cause the memory system to:
output, by the third circuitry, real time failure indications associated with the plurality of vias based at least in part on the output signaling.

16. The memory system of claim 15, wherein the processing circuitry is further configured to cause the memory system to:
receive, at the third circuitry, a counter value associated with the real time failure indications associated with the plurality of vias, wherein the failure information associated with the plurality of vias is further based at least in part on the counter value.

17. The memory system of claim 9, wherein the failure information indicates a failure associated with the plurality of vias, and the processing circuitry is further configured to cause the memory system to:
receive, at the second circuitry, second control signaling indicating a third memory die of the stack of memory dies based at least in part on the failure associated with the plurality of vias;
routing, used the first circuitry, second test signaling from the third memory die to the second memory die through a portion of the via based at least in part on the second control signaling; and
store, by the third circuitry, failure information associated with the portion of each of the plurality of vias based at least in part on second output signaling from the second memory die, wherein the second output signaling is based at least in part on the second test signaling.

18. A method by a memory system, comprising:
receiving control signaling by at least one memory die of a stack of memory dies of the memory system, wherein each memory die of the stack of memory dies comprises first circuitry coupled with a plurality of vias and second circuitry that receives the control signaling, wherein the plurality of vias extend through the stack of memory dies and route signaling between at least a first memory die of the stack of memory dies and a second memory die of the stack of memory dies;
routing, using the first circuitry, test signaling between the first memory die and the second memory die through a via of the plurality of vias based at least in part on receiving the control signaling; and
storing, by third circuitry that is coupled with the second memory die, failure information associated with the plurality of vias based at least in part on output signaling from the second memory die, wherein the output signaling is based at least in part on routing the test signaling between the first memory die and the second memory die.

19. The method of claim 18, wherein routing the test signaling from the first memory die to the second memory die comprises:
routing the test signaling from the first memory die to a first node of the second memory die through a reference via that is coupled with the first node; and
routing the test signaling from the first memory die to a second node of the second memory die through the via of the plurality of vias, wherein the first node and the second node are associated with the output signaling.

20. The method of claim 19, further comprising:
comparing the output signaling from the first node to the output signaling from the second node to determine the failure information.
